(19) United States
(12) Patent Application Publication
(10) Pub. No.: US 2018/0035616 A1
(43) Pub. Date: Feb. 8, 2018

(54) LED GROW SYSTEM

(71) Applicant: Emiton LED Technologies, LLC, Park City, UT (US)

(72) Inventor: John Wagner, Park City, UT (US)

(21) Appl. No.: 15/667,563

(22) Filed: Aug. 2, 2017

Related U.S. Application Data
(60) Provisional application No. 62/370,120, filed on Aug. 2, 2016.

(51) Int. Cl. A01G 7/04; H04L 29/08; H05B 33/08; A01G 31/02; A01G 9/24

(52) U.S. Cl. CPC A01G 7/045; A01G 31/02; A01G 9/24; H05B 33/0845; H04L 67/125

(57) ABSTRACT

An LED grow system is disclosed. The LED grow system comprises: a wireless network; a red LED; a blue LED; a light controller coupled with the red LED and the blue LED and in communication with wireless network; and a mobile device in communication with the wireless network. The mobile device may include: a database having a plurality of grow profiles, where each of the grow profiles specify at least a relative intensity for the red LED, a relative intensity for the blue light, and an illumination time period; and an application executing on the mobile device that controls the illumination of the red LED and the blue LED via the light controller according to the plurality of grow profiles specified within the database.

### SUMMARY

An LED grow system is disclosed. The LED grow system comprises: a wireless network; a red LED; a blue LED; a light controller coupled with the red LED and the blue LED and in communication with wireless network; and a mobile device in communication with the wireless network. The mobile device may include: a database having a plurality of grow profiles, where each of the grow profiles specify at least a relative intensity for the red LED, a relative intensity for the blue light, and an illumination time period; and an application executing on the mobile device that controls the illumination of the red LED and the blue LED via the light controller according to the plurality of grow profiles specified within the database.

These illustrative embodiments are mentioned not to limit or define the disclosure, but to provide examples to aid understanding thereof. Additional embodiments are discussed in the Detailed Description, and further description is provided there. Advantages offered by one or more of the various embodiments may be further understood by examining this specification or by practicing one or more embodiments presented.

### BRIEF DESCRIPTION OF THE FIGURES

These and other features, aspects, and advantages of the present disclosure are better understood when the following Detailed Description is read with reference to the accompanying drawings.

FIG. 1 illustrates an LED grow system according to some embodiments.

FIG. 2 is an example flowchart of a process that can be used to illuminate a plant for photosynthesis purposes.

FIG. 3 is an example flowchart of a process that can be used to illuminate a plant for photosynthesis purposes.

FIG. 4 shows an illustrative computational system for performing functionality to facilitate implementation of embodiments described herein.

FIG. 5 illustrates an example light absorption profile for a plant.

### DETAILED DESCRIPTION

Systems and methods are disclosed for LED lights for use in hydroponic, artificial light, or indoor plant growing environments. In some embodiments, the LED lights may be tuned to produce a different grow profile. A grow profile may include a spectral profile, intensity profile, and/or timing profile over the course of a plants' growth cycle. The grow profile may also include timing about when to change between profiles and/or the duration of profile over time or in a given day.

For example, the LED lights may be tuned to produce a first light profile during a first growth cycle, a second light profile during a second growth cycle, and a third light profile during a third growth cycle. A light profile, for example, may include a light spectrum, a light intensity, and/or the periods in a day when the LED lights are turned on. In some embodiments, a light profile may change the intensity of light and/or the spectrum of light based on the time of day. Various other light profiles may be used during various other life cycles of a plant.

For example, for some leafy vegetables, an LED positioned to illuminate vegetables for photosynthesis purposes may produce blue light (e.g., about 380 nm±50 nm) for less than about 18 hours per day during the early growth stage. The LED may be changed to produce a spectrum of light that includes about 70% blue light (e.g., about 380 nm±50 nm) and/or 30% red light (e.g., about 750 nm±50 nm) for less than about 18 hours per day during the vegetative stage.

As another example, for some vine like crops, the LED light may produce blue light (e.g., about 380 nm±50 nm) for less than about 18 hours per day during the early growth stage. The LED may be changed to produce a spectrum of light that includes about 70% blue light (e.g., about 380 nm±50 nm) and/or 30% red light (e.g., about 750 nm±50 nm) for less than about 18 hours per day during the vegetative stage. The LED may be changed to produce a spectrum of light that includes about 80% red light (e.g., about 750 nm±50 nm), 20% white light, and/or 20% blue light (e.g., about 380 nm±50 nm) for less than about 18 hours per day during the flower, bloom, bud, and/or blossom stage.

As another example, for some herbs crops, the LED light may produce blue light (e.g., about 380 nm±50 nm) for less than about 18 hours per day during the early growth stage. The LED may be changed to produce a spectrum of light that includes about 70% blue light (e.g., about 380 nm±50 nm) and/or 30% red light (e.g., about 750 nm±50 nm) for less than about 18 hours per day during the vegetative stage. The LED may be changed to produce a spectrum of light that includes about 50% blue light (e.g., about 380 nm±50 nm) and/or 50% red light (e.g., about 750 nm±50 nm) for less than about 24 hours per day during the super vegetative or no flower stage (e.g., “mother room”). The LED may be changed to produce a spectrum of light that includes about 80% red light (e.g., about 750 nm±50 nm) and 20% blue light (e.g., about 380 nm±50 nm) or 80% red light and 20% blue light for less than about 10 hours per day during the flower, bloom, bud, and/or blossom stage for about 10 hours. In addition, during the flower, bloom, bud, and/or blossom stage the LED may be changed to produce a spectrum of light that includes about 80% red light (e.g., about 750 nm±50 nm) for less than about 2 hours per day and/or may do so at two times the intensity. Thus, in the flower, bloom, bud, and/or blossom stage, the LED lights may be tuned to different stages for different periods of time.

In some embodiments, the LED lights may be changed to white light (or any light spectrum, for example, chosen by the horticulturalist) during harvesting, inspection, grooming, tending, etc.

Some embodiments include an LED lighting system that may be designed to allow an operator or algorithm to control the wavelength, spectrum, timing and/or intensity of light. In some embodiments, each plant, plant type, genus, species, category, etc. may have a defined grow profile designed for the specific plant, plant type, genus, species, category, etc.

In some embodiments, the grow profile may change from one profile to another based on timing (e.g., number of days in the given stage), sensor data (e.g., cameras or spectral data indicating that a plant has transition from one stage to another), and/or user input. For example, for a given plant it may be determined that the given plant may be in the growth stage for about 24 days and then in the vegetative stage for about 30 days. The grow profile may change from a first growth grow profile to a second vegetative profile after 24 days.

Some embodiments may include recipes and/or algorithms designed to maximize various aspects of plant growth/qualities, etc. that are specific to individual species. These recipes and/or algorithms may be stored in a digital storage location and may be used by a controller to control the illumination of LEDs.

Some embodiments may include a system that controls grow profiles for different plants (e.g., plant, plant type, genus, species, category, etc.) at the same time. For instance, a first plant may be growing in a first zone (e.g., a certain row, of a given rack, of a growing system) and a second plant may be growing in a second zone (e.g., a certain row, of a given rack, of a growing system). In some embodiments, a controller (e.g., computer, processor, microprocessor, FPGA, computational system 400, etc.) may control the lighting of the first plant with a first grow profile and the lighting of the second plant with a second grow profile simultaneously where the two profiles are different and the associated LEDs provide different light spectrum, intensity, and/or timing.

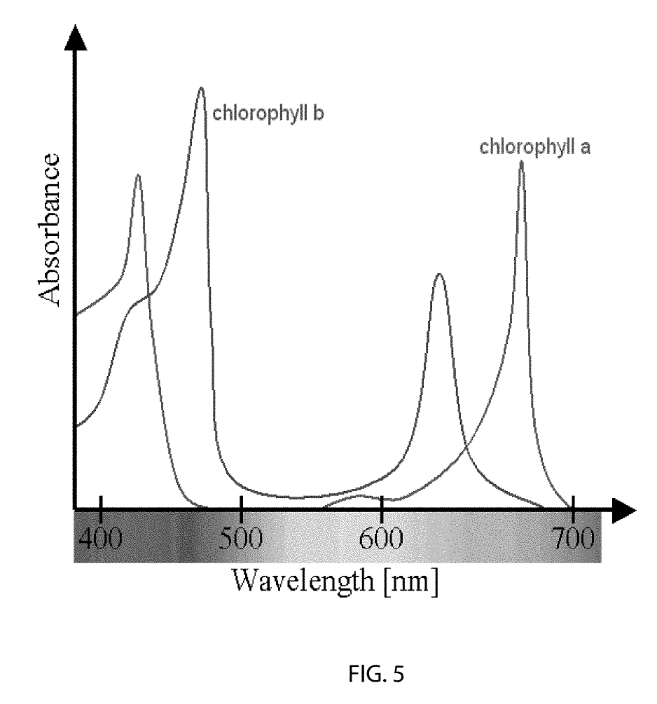

In some embodiments, the grow profiles may be targeted to increase light absorption of a plant. FIG. 5 illustrates an example light absorption profile for a plant.

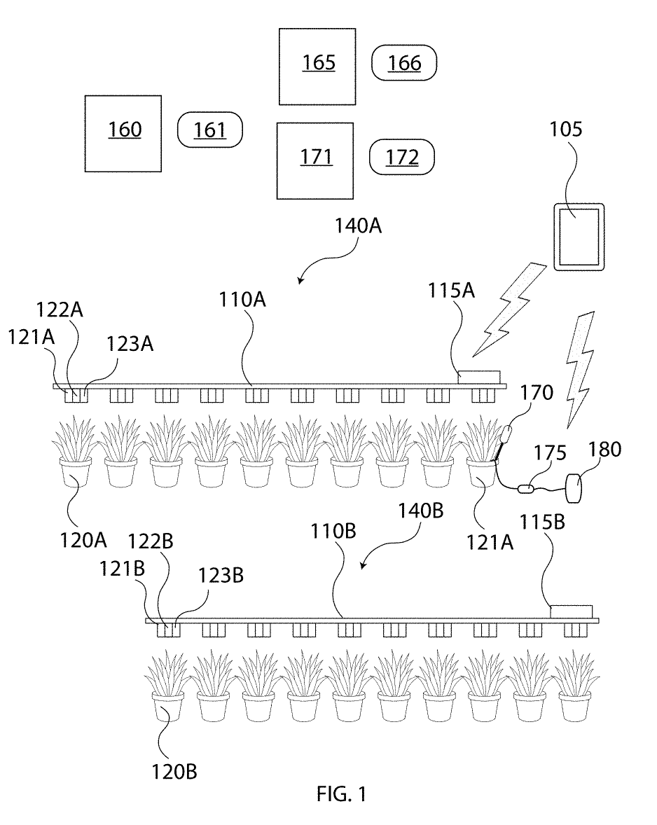

FIG. 1 illustrates an LED grow system 100 according to some embodiments. LED grow system 100, for example, includes a mobile device 105, a first grow line 140A, and a second grow line 140B. While two grow lines are shown in FIG. 1, any number of grow lines may be included. In addition, while grow line 140A and grow line 140B are shown having the same components in the same quantities, the two grow lines may have different components and/or components in different quantities.

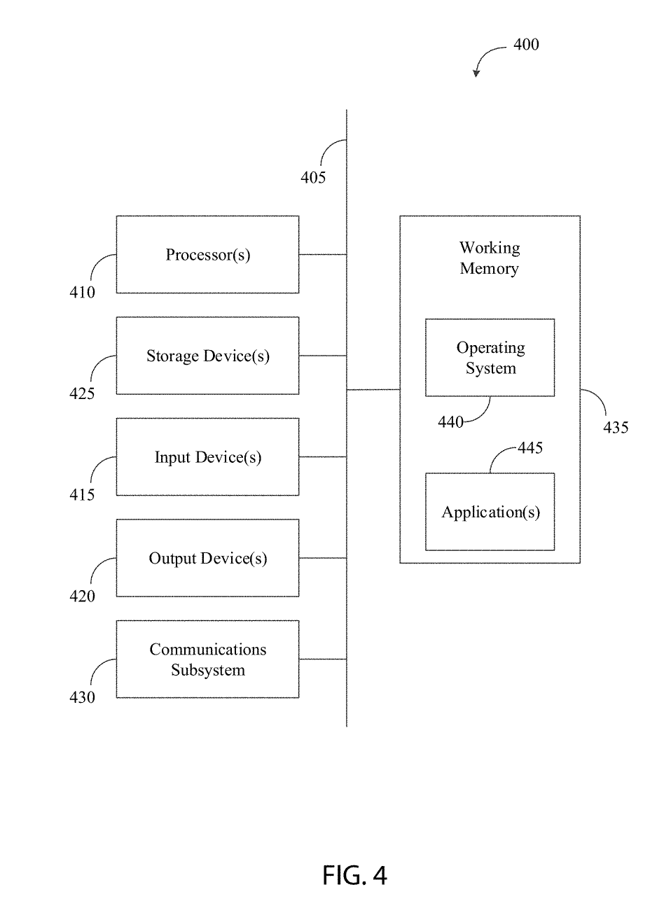

The mobile device 105, for example, may include one or more components of computational system 400 shown in FIG. 4. The mobile device 105, for example, may include a tablet, mobile phone, mobile device, laptop computer, desktop computer, etc. In some embodiments, the mobile device 105 may be in communication with a cloud based system that may, for example, communicate software upgrades, communicate grow profiles, communicate approval for use of the various embodiments, etc. In some embodiments, the mobile device 105 may communicate grow cycle information and plant health information to the cloud based system. In some embodiments, the cloud based system may provide an indication that a given application executing on the mobile device 105 is approved or not approved for execution such as, for example, when subscription fees have or have not been paid. In some embodiments, sensor data (e.g., temperature, humidity, CO2 levels, moisture levels, nutrient levels, spectrum, intensity, etc. may be communicated to the cloud based system.

In some embodiments, grow line 140A may include a controller 115A, and a plurality of light sets coupled with a structure 110A. The structure 110A, for example, may include any type of physical structure including a beam, poles, a ceiling, etc.

Each of the plurality of light sets, for example, may include at least three different lights. For example, a light set may include a red light 121A, a blue light 122A, and/or a green light 123A. The red light 121A, for example, may produce light with a light spectrum between 580 nm to 750 nm. In some embodiments, the red light 121A may be a red LED light that produces light at 710 nm. The blue light 122A, for example, may produce light with a light spectrum between 350 nm to 460 nm. In some embodiments, the blue light 122A may produce blue light at 380 nm. The green light 123A, for example, may produce light with a light spectrum between 460 nm to 580 nm. In some embodiments, the green light 123A may be omitted. In some embodiments, additional lights may be included such as, for example, one or more soft white lights (e.g., at 2700K-3000K), one or more bright white/cool white lights (e.g., at 3500K-4100K), one or more daylights (e.g., at 5000K-6500K), one or more UV lights (e.g., 320 nm-290 nm).

Each of the plurality of light sets may include any type of light such as, for example, LEDs, metal-halide lights, incandescent lights, fluorescent lights, halogen lights, high-intensity discharge lights, neon lights, etc.

In some embodiments, the LED grow system 100 may include a humidifier 160 and/or a humidity sensor 161. The humidifier 160 and/or a humidity sensor 161 may communicate with either the mobile device 105 and/or a controller 115 (e.g., either controller 115A or controller 115B). The mobile device 105, for example, may receive humidity measurement values from the humidity sensor 161. If the humidity values are above or below a target humidity value (e.g., as determined from A grow profile) the mobile device 105 may control the humidifier 160 to increase or decrease the humidity in the area near the plants until the humidity values are within target humidity tolerances of the predetermine humidity value.

In some embodiments, the LED grow system 100 may include an HVAC system 165 and/or a thermometer 166. The HVAC system 165 and/or a thermometer 166 may communicate with either the mobile device 105 and/or a controller 115 (e.g., either controller 115A or controller 115B). The mobile device 105, for example, may receive temperature measurement values from the thermometer 166. If the temperature values are above or below a target temperature value (e.g., as determined from A grow profile) the mobile device 105 may control the HVAC system 165 to increase or decrease the temperature in the area near the plants until the temperature values are within target temperature tolerances of the predetermine temperature value.

In some embodiments, the LED grow system 100 may include a CO₂ pump 171 and/or a CO₂ sensor 172. The CO₂ pump 171 and/or a CO₂ sensor 172 may communicate with either the mobile device 105 and/or a controller 115 (e.g., either controller 115A or controller 115B). The mobile device 105, for example, may receive CO₂ measurement values from the CO₂ sensor 172. If the CO₂ values are above or below a target CO₂ value (e.g., as determined from a grow profile) the mobile device 105 may control the CO₂ pump 171 to increase or decrease the CO₂ in the area near the plants until the CO₂ values are within target CO₂ tolerances of the predetermine CO_{2 value.}

In some embodiments, the LED grow system 100 may include one or more soil moisture sensors 170 and a water system. The water system may include a water source 180 and/or a water control valve 175. The water control valve 175 and/or the one or more soil moisture sensors 170 may communicate with either the mobile device 105 and/or a controller 115 (e.g., either controller 115A or controller 115B). The mobile device 105, for example, may receive soil moisture values from the one or more soil moisture sensors 170. If the soil moisture values are above or below a target soil moisture value (e.g., as determined from A grow profile) the mobile device 105 may control the water control valve 175 to increase or decrease the water being supplied to a plant or a series of plants until the soil moisture values are within target soil moisture tolerances of the predetermine soil moisture value.

In some embodiments, the soil moisture sensor 170 may include a solar panel that may be used to charge a battery in the soil moisture sensor 170 using light from the lights 121, 122, 123. The battery may then power the soil moisture sensor 170. In some embodiments, the soil moisture sensor 170 may also include a wireless transceiver that may be used communicate with the mobile device 105.

In some embodiments, the CO₂ sensor 172 may include a solar panel that may be used to charge a battery in the CO₂ sensor 172 using light from one or more lights (e.g., lights 121, 122, 123). The battery may then power the CO₂ sensor 172. In some embodiments, the CO₂ sensor 172 may also include a wireless transceiver that may be used communicate with the mobile device 105.

In some embodiments, the humidity sensor 161 may include a solar panel that may be used to charge a battery in the humidity sensor 161 using light from one or more lights (e.g., lights 121, 122, 123). The battery may then power the humidity sensor 161. In some embodiments, the humidity sensor 161 may also include a wireless transceiver that may be used communicate with the mobile device 105.

In some embodiments, the thermometer 166 may include a solar panel that may be used to charge a battery in the thermometer 166 using light from one or more lights (e.g., lights 121, 122, 123). The battery may then power the thermometer 166. In some embodiments, the thermometer 166 may also include a wireless transceiver that may be used communicate with the mobile device 105.

The controller 115A, for example, may include one or more components of computational system 400 shown in FIG. 4. For example, controller 115A may include a wireless transceiver that may communicate with the mobile device 105 via any wireless protocol such as, for example, Wi-Fi or Bluetooth. For example, the mobile device 105 may send lighting control instructions to the controller 115A. The controller 115A, for example, may turn on or turn off lights in accordance with the lighting control instructions. The lighting control instructions, for example, may include instructions to turn on light of specific colors, and/or instructions to illuminate or not illuminate the plants 120A for specific period of time.

In some embodiments, the LED grow system 100 may include a light sensor that detects the spectrum of light incident on or near the plant. The light sensor may provide feedback to the mobile device 105. Using this data, the mobile device 105 may adjust the intensity of one or more lights (e.g., lights 121, 122, 123).

In some embodiments, the LED grow system 100 may include a nutrient dispensing device that may, for example, dispense fertilizer and/or other nutrients to the plants. For example, a nutrient dispensing system may dispense nutrients in water in a hydroponic system.

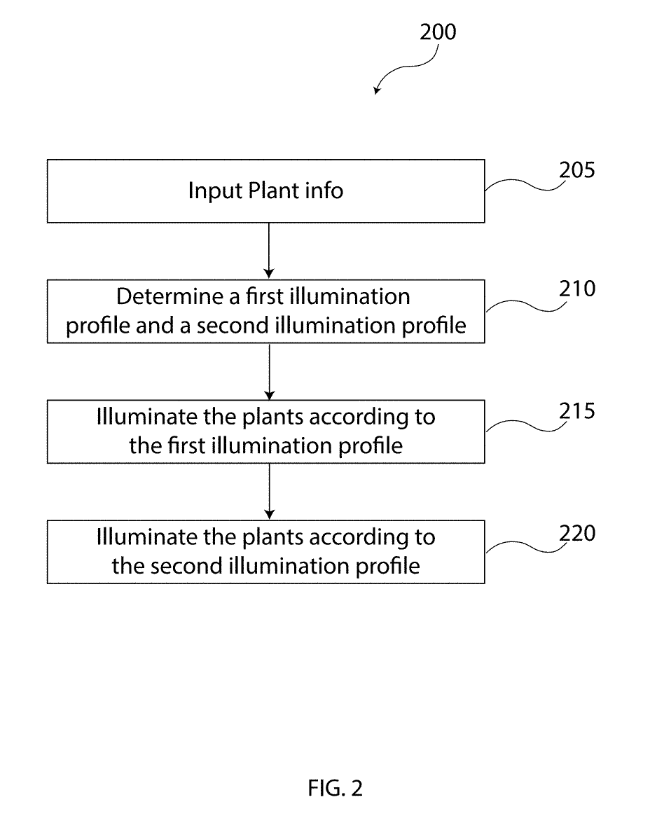

FIG. 2 is an example flowchart of a process 200 that can be used to illuminate a plant for photosynthesis purposes. At block 205, information about a plant can be entered into computational system 400. The information may include the name of the plant, the plant type, the plant category, the plant species, the plant genus, etc. Any type of plant information may be entered. In some embodiments, the plant information can be entered via the mobile device 105. In some embodiments, a dropdown menu may be provided that allows a user to select between a number of plants species, plant categories, and/or plant genus, etc. For example, the mobile device 105 can present a dropdown menu that allows the user to select the type of plant.

At block 210 a first grow profile and a second grow profile may be determined based on the plant information. The first grow profile and/or the second grow profile may include different spectral, intensity, and/or timing profiles. The first grow profile and/or the second grow profile may be selected from a memory based on the on the plant information. Various types of logic, lookup tables, etc. can be used to determine the first grow profile and/or the second grow profile for the plant. The first grow profile, for example, may be associated with a growth stage (e.g., early growth, vegetative, flower, bloom, bud, blossom, super vegetative, no flower, harvest, etc.) of the plant. The second grow profile, for example, may be associated with a different growth stage of the plant (e.g., early growth, vegetative, flower, bloom, bud, blossom, super vegetative, no flower, harvest, etc.). The first grow profile and/or the second grow profile, for example, may be retrieved from a database that correlates plant information with a first grow profile and/or a second grow profile.

In some embodiments, the mobile device 105 can communicate the first grow profile and/or the second grow profile to the controller 115A and/or the controller 115B. In some embodiments, the mobile device 105 can communicate a different first grow profile to the controller 115A than communicated to the controller 115B. Similarly, the mobile device 105 can communicate a different second grow profile to the controller 115A than communicated to the controller 115B.

Table 1 and Table 2 illustrate two different sets of grow profiles that may be used for various type of plants. The set of grow profiles shown in Table 1 may, for example, be used with vine type plants. The set of grow profiles shown in Table 2 may, for example, be used with leafy plants such as, for example, cannabis. In these examples, green lights are not used, although a green light may also be included. The duration per day is the amount of time the lights are on during a 24-hour period. In Table 1 and Table 2, the percentages indicate a relative intensity of the light being produced by the lights during a given grow profile.

In Table 2, under the fifth grow profile, for example, the red light may be increased to 100% intensity for 2 hour intervals. This may occur, for example, in conjunction with the fourth profile such as during the 10 hours when the lights are illuminated. In some examples, the duration per day of the fourth grow profile may extend to 12 or 14 hours. In some embodiments, the duration per day of the third grow profile may be 16, 18, 20, or 22 hours.

TABLE 1
Example grow profiles for a plant lifecycle.

| | | Second | | Fourth |
|---|---|---|---|---|
| | First Grow | Grow | Third Grow | Grow |
| | Profile | Profile | Profile | Profile |
| Hours per day | 18 | 18 | 18 | 16 |
| Red light | | 25% | 75% | |
| Blue light | 100% | 65% | 10% | |
| White light | | 10% | 10% | 100% |

TABLE 2
Example grow profiles for a plant lifecycle.

| | First | Second | Third | Fourth | Fifth | |
|---|---|---|---|---|---|---|
| | Grow | Grow | Grow | Grow | Grow | Sixth Grow |
| | Profile | Profile | Profile | Profile | Profile | Profile |
| Duration | 18 | 18 | 24 | 10 | 2 | 16 |
| per day | | | | | | |
| Red light | | 25% | 40% | 75% | 100%* | |
| Blue light | 100% | 65% | 40% | 15% | | |
| White | | 10% | 20% | 10% | | 100% |
| light | | | | | | |

While Table 1 and Table 2 illustrate two different sets of example grow profiles, various other sets of grow profiles may be used without limitation.

At block 215 plants (e.g., plant 120) may be illuminated with lights (e.g., lights 121, 122, and/or 123, and/or additional lights) based on the first grow profile. Block 215 may repeat a specific number of times before proceeding to block 220. At block 220 plants (e.g., plant 120) may be illuminated with lights (e.g., lights 121, 122, and/or 123, and/or additional lights) based on the second grow profile. Block 220 may repeat a specific number of times. Process 200 may extend to additional grow profiles such as, for example, those shown in Table 1 and/or Table 2.

In some embodiments, each grow profile may also include a target soil moisture value and/or soil moisture tolerances. In some embodiments, each grow profile may also include a target temperature value and/or temperature tolerances. In some embodiments, each grow profile may also include a target humidity value and/or humidity tolerances.

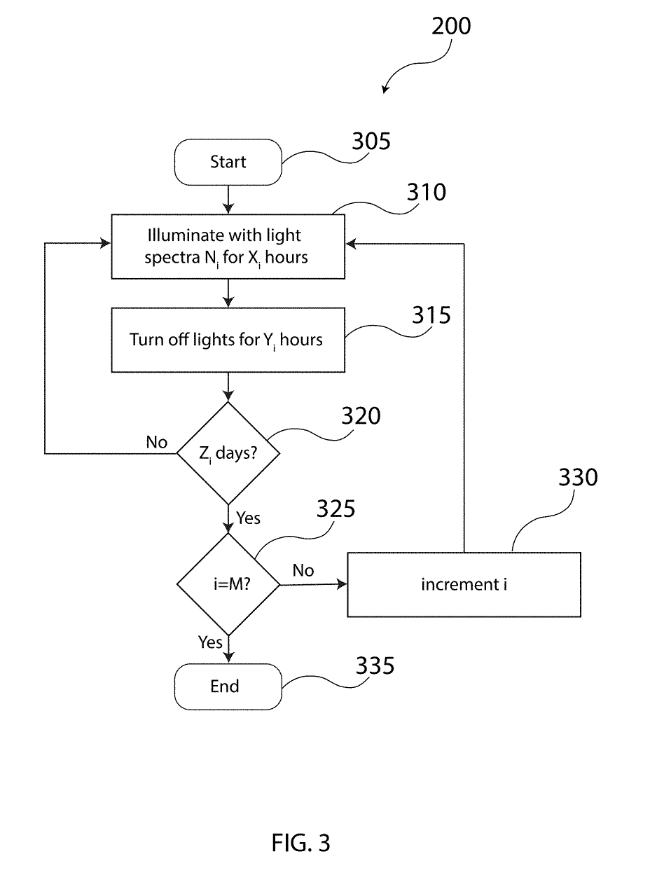

FIG. 3 is an example flowchart of a process 300 that can be used to illuminate a plant for photosynthesis purposes. Process 300, for example, may be executed by an application on mobile device 105 to control various components of the grow system 100.

Process 300 starts at block 305. For example, process 300 can start when a user presses a button on a touch screen of mobile device 105. The process 300 can start after a user has planted on or more plants and is ready to start the growing the plants.

At block 310 the plants are illuminated with light Nᵢ for Xᵢ hours, where i indicates the grow profile. At first i may equal 1. According to the set of grow profiles shown in Table 2, when i=1, the plants are illuminated for 18 hours with 100% blue light.

At block 315 the lights may be turned off for Yᵢ hours. In some embodiments, Yᵢ=24−Xᵢ. Using the grow profiles in Table 2, when i=1, for example, the lights are turned off for 6 hours.

Blocks 310 and 315 may be repeated for Zᵢ days where Zᵢ represents the number of days the grow profile is repeated before moving to the next grow profile. Typically, for example, Zᵢ can represent the number of days a given plant may be in a given growth state such as, for example, an early growth stage, vegetative stage, super vegetative stage, flowing stage, blossom stage, bloom stage, harvest stage, etc. In some grow profiles Zᵢ may not be directly correlated with a grow stage, but may, for example, be a subset of grow stage such as, for example, the fifth grow profile shown in Table 2.

At block 325 the process 300 can determine whether i=M, where M represents the number of grow profiles. For example, in Table 3, M=6. If i=M process 300 ends at block 335. Otherwise, process 300 proceeds to block 330 where i is incremented and the process repeats with the next grow profile.

In some embodiments, process 300 may include blocks for testing the soil moisture, for example, using the soil moisture sensor 170; and determining whether the soil moisture is within tolerances of a target soil moisture for the grow profile. If the soil moisture is outside the tolerances of a target soil moisture for the grow profile then plants may be watered, for example, using water control valve 175.

In some embodiments, process 300 may include blocks for testing the humidity, for example using the humidity sensor 161; and determining whether the humidity is within tolerances of a humidity for the grow profile. If the humidity is outside the tolerances of a target humidity for the grow profile then humidity within the grow chamber may be changed, for example, using humidifier 160.

In some embodiments, process 300 may include blocks for testing the temperature, for example, using the thermometer 166; and determining whether the temperature is within tolerances of a target temperature for the grow profile. If the temperature is outside the tolerances of the target temperature for the grow profile then temperature within the grow chamber may be changed, for example, using HVAC system 165.

In some embodiments, a lighting profile may be a default lighting profile. In the event a process is interrupted, the lights illuminate the plants with the default light profile. For example, if the mobile device 105 is shut down, or communication between the mobile device 105 and the controllers or lights is interrupted, the lights may illuminate the plants according to a default profile. The default profile, for example, may include illumination with all the lights or a select number of lights or any other profile.

The computational system 400, shown in FIG. 4 can be used to perform any of the embodiments of the invention. For example, computational system 400 can be used to execute methods 200 and/or 300. As another example, computational system 400 can be used perform any calculation, identification and/or determination described here. Computational system 400 includes hardware elements that can be electrically coupled via a bus 405 (or may otherwise be in communication, as appropriate). The hardware elements can include one or more processors 410, including without limitation one or more general-purpose processors and/or one or more special-purpose processors (such as digital signal processing chips, graphics acceleration chips, and/or the like); one or more input devices 415, which can include without limitation a mouse, a keyboard and/or the like; and one or more output devices 420, which can include without limitation a display device, a printer and/or the like.

The computational system 400 may further include (and/or be in communication with) one or more storage devices 425, which can include, without limitation, local and/or network accessible storage and/or can include, without limitation, a disk drive, a drive array, an optical storage device, a solid-state storage device, such as a random-access memory (“RAM”) and/or a read-only memory (“ROM”), which can be programmable, flash-updateable and/or the like. The computational system 400 might also include a communications subsystem 430, which can include without limitation a modem, a network card (wireless or wired), an infrared communication device, a wireless communication device and/or chipset (such as a Bluetooth device, an 802.6 device, a Wi-Fi device, a WiMAX device, cellular communication facilities, etc.), and/or the like. The communications subsystem 430 may permit data to be exchanged with a network (such as the network described below, to name one example), and/or any other devices described herein. In many embodiments, the computational system 400 will further include a working memory 435, which can include a RAM or ROM device, as described above.

The computational system 400 also can include software elements, shown as being currently located within the working memory 435, including an operating system 440 and/or other code, such as one or more application programs 445, which may include computer programs of the invention, and/or may be designed to implement methods of the invention and/or configure systems of the invention, as described herein. For example, one or more procedures described with respect to the method(s) discussed above might be implemented as code and/or instructions executable by a computer (and/or a processor within a computer). A set of these instructions and/or codes might be stored on a computer-readable storage medium, such as the storage device(s) 425 described above.

In some cases, the storage medium might be incorporated within the computational system 400 or in communication with the computational system 400. In other embodiments, the storage medium might be separate from a computational system 400 (e.g., a removable medium, such as a compact disc, etc.), and/or provided in an installation package, such that the storage medium can be used to program a general-purpose computer with the instructions/code stored thereon. These instructions might take the form of executable code, which is executable by the computational system 400 and/or might take the form of source and/or installable code, which, upon compilation and/or installation on the computational system 400 (e.g., using any of a variety of generally available compilers, installation programs, compression/decompression utilities, etc.) then takes the form of executable code.

Numerous specific details are set forth herein to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied, for example, blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. An LED grow system comprising:
a wireless network;
a red LED;
a blue LED;
a light controller coupled with the red LED and the blue LED and in communication with wireless network;
a mobile device in communication with the wireless network, the mobile device comprising:
a database having a plurality of grow profiles, where each of the grow profiles specify at least a relative intensity for the red LED, a relative intensity for the blue light, and an illumination time period; and
an application executing on the mobile device that controls the illumination of the red LED and the blue LED via the light controller according to the plurality of grow profiles specified within the database.

2. The LED grow system according to claim 1, further comprising an HVAC system and a thermometer coupled with the wireless network, wherein the plurality of grow profiles within the database specifies target temperature tolerances, and the application executing on the mobile device determines a current grow temperature measurement is outside the target temperature tolerances and controls the HVAC system to change the current grow temperature to be within the target temperature tolerances.

3. The LED grow system according to claim 1, further comprising a humidifier and a humidity sensor coupled with the wireless network, wherein the plurality of grow profiles within the database specifies target humidity tolerances, and the application executing on the mobile device determines a current grow humidity measurement is outside the target humidity tolerances and controls the humidifier to change the grow humidity to be within the target humidity tolerances.

4. The LED grow system according to claim 1, further comprising a watering system and a soil moisture sensor coupled with the wireless network, wherein the plurality of grow profiles within the database specifies target soil moisture tolerances, and the application executing on the mobile device determines a current grow soil moisture measurement is outside the target soil moisture tolerances for a given grow profile and controls the watering system to change the amount of water provided to plants until the soil moisture is within the target soil moisture tolerances.

5. A method comprising:
illuminating a plant with a red light at a first red light relative intensity for a first period of time;
illuminating a plant with a blue light at a first blue light relative intensity for the first period of time;
determining that the first time period has past;
illuminating a plant with a red light at a second red light relative intensity for a second period of time;
illuminating a plant with a blue light at a second blue light relative intensity for the second period of time;
determining that the second time period has past;
illuminating a plant with a red light at a third red light relative intensity for a third period of time;
illuminating a plant with a blue light at a third blue light relative intensity for the third period of time; and
determining that the third time period has past.

6. The method according to claim 5, further comprising:
determining a current grow temperature measurement is outside target temperature tolerances; and
controlling an HVAC system to change the grow temperature to be within the target temperature tolerances.

7. The method according to claim 5, further comprising:
determining a current grow humidity measurement is outside target humidity tolerances; and
controlling a humidifier to change the grow humidity to be within the target humidity tolerances.

8. The method according to claim 5, further comprising:
determining a current grow soil moisture measurement is outside a target soil moisture tolerances for a given grow profile; and
controlling the watering system to change the amount of water provided to plants until the soil moisture is within the target soil moisture tolerances.
